(19) United States
(12) Patent Application Publication
(10) Pub. No.: US 2008/0070372 A1
(43) Pub. Date: Mar. 20, 2008

(54) METHOD OF MANUFACTURING A SEMICONDUCTOR DEVICE

(75) Inventors: Yong-Hoon SON, Gyeonggi-do (KR); Si-Young CHOI, Gyeonggi-do (KR); Jong-Wook LEE, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/852,901

(22) Filed: Sep. 10, 2007

(30) Foreign Application Priority Data
Sep. 19, 2006 (KR) 2006-0090841

(51) Int. Cl. H01L 21/20; H01L 21/336

(52) U.S. Cl. 438/308; 438/487; 257/E21.09; 257/E21.409

(57) ABSTRACT

In a method of manufacturing a semiconductor device, an insulating layer pattern defining at least one opening partially exposing a semiconductor substrate is formed on a semiconductor substrate including a single crystalline material. An amorphous thin layer is formed on the insulating layer pattern to fill up the opening. The amorphous thin layer is transformed into a single crystalline thin layer by providing the amorphous thin layer with a laser beam having sufficient energy to melt the amorphous thin layer. Here, the semiconductor substrate partially exposed through the opening is used as a seed. A gate pattern is formed on the single crystalline thin layer. Source/drain regions are formed at surface portions of the single crystalline thin layer adjacent to both sidewalls of the gate pattern.

### CROSS-REFERENCE TO RELATED APPLICATION

This application claims priority under 35 USC §119 to Korean Patent Application No. 2006-90841, filed on Sep. 19, 2006, the contents of which are herein incorporated by reference in their entirety.

### BACKGROUND

1. Technical Field

The present invention relates to a method of manufacturing a semiconductor device. More particularly, the present invention relates to a method of manufacturing a semiconductor device capable of forming a unit device such as a metal oxide semiconductor field effect transistor (MOSFET) on a single crystalline thin layer formed on an insulating layer.

2. Description of the Related Art

Recently, semiconductor devices have been required to have a high integration degree and a high operation speed. A unit device such as a metal oxide semiconductor field effect transistor (MOSFET) may be formed on a bulk semiconductor substrate to manufacture the semiconductor device. However, when the MOSFET is formed on the bulk semiconductor substrate, a length of a channel formed in the semiconductor device may be reduced.

To overcome the above problem, techniques such as a silicon-on-insulator (SOI) process have been developed. When the SOI process is employed, a unit device such as the MOSFET is formed on a single crystalline thin layer after the single crystalline thin layer is formed on an insulating layer.

When the techniques such as the SOI process are employed to manufacture the semiconductor device, the unit device formed on the semiconductor substrate may be separated from the semiconductor substrate by an insulator, e.g., a buried oxide layer, so that power consumption may be reduced. In addition, junction capacitance is reduced so that a high operation speed may be achieved. A latch-up phenomenon due to a bipolar junction transistor (BJT) may also be reduced. Furthermore, processes required for forming a well using an ion implantation may be omitted and a junction leakage may be sufficiently reduced by minimizing a junction depletion region.

Accordingly, the semiconductor device manufactured using techniques such as the SOI process may have the above-mentioned advantages.

However, the processes of manufacturing the semiconductor device using the techniques such as the SOI process are relatively complex. In addition, a cost required for manufacturing the semiconductor device using the techniques such as the SOI process may be greater than a cost required for manufacturing the semiconductor device on the bulk semiconductor substrate. The present invention addresses these and other disadvantages of the conventional art.

### SUMMARY

An example embodiment of the present invention provides a method of manufacturing a semiconductor substrate capable of effectively obtaining the semiconductor substrate on which an insulating layer pattern and a single crystalline thin layer are sequentially formed by relatively simple processes. An example embodiment of the present invention also provides a method of manufacturing the semiconductor device capable of effectively forming a unit device such as a metal oxide semiconductor field effect transistor (MOSFET) on the single crystalline thin layer formed on the semiconductor substrate.

In accordance with some embodiments of the present invention, there is provided a method of manufacturing a semiconductor device. In the method, an insulating layer pattern defining at least one opening partially exposing a semiconductor substrate is formed on the semiconductor substrate including a single crystalline material. An amorphous thin layer is then formed on the insulating layer pattern to fill up the opening. The amorphous thin layer is then transformed into a single crystalline thin layer by providing the amorphous thin layer with a laser beam having sufficient energy to melt the amorphous thin layer. The semiconductor substrate partially exposed through the opening is used as a seed when the melted amorphous thin layer is transformed into the single crystalline thin layer.

Therefore, when the above process is employed to manufacture the semiconductor device, the semiconductor device may have the advantages generally obtained by applying techniques such as a silicon-on-insulator (SOI) process.

### BRIEF DESCRIPTION OF THE DRAWINGS

The above and other features and advantages of the present invention will become readily apparent by reference to the following detailed description when considered in conjunction with the accompanying drawings wherein:

FIGS. 1A to 1E are cross-sectional views illustrating a method of manufacturing a semiconductor device in accordance with an example embodiment of the present invention; and

FIGS. 2A to 2D are cross-sectional views illustrating a method of manufacturing a semiconductor device in accordance with another example embodiment of the present invention.

### DETAILED DESCRIPTION

The present invention is described more fully hereinafter with reference to the accompanying drawings, in which example embodiments of the present invention are shown. The present invention may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on” or “connected to” another element or layer, it can be directly on, connected or coupled to the other element or layer or intervening elements or layers may be present. In contrast, when an element is referred to as being “directly on” or “directly connected to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the present invention are described herein with reference to cross-section illustrations that are schematic illustrations of idealized embodiments (and intermediate structures) of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

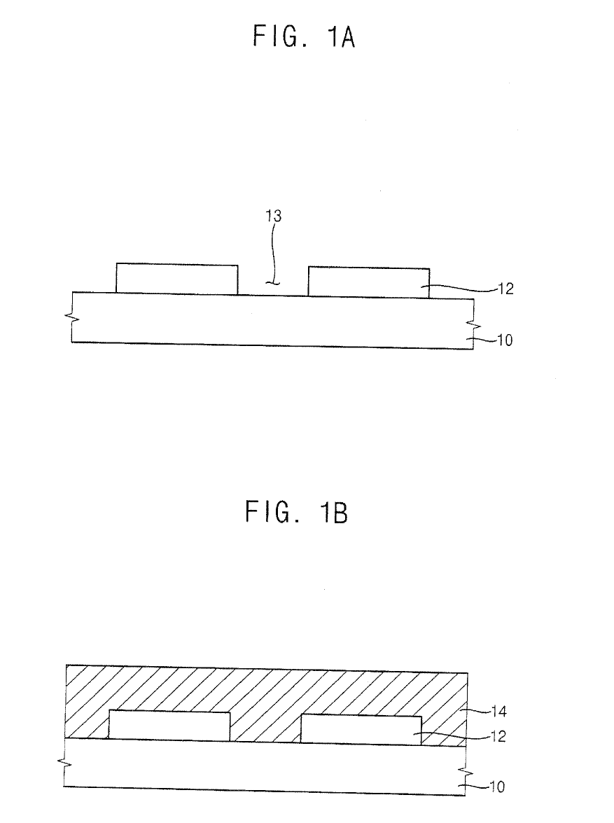

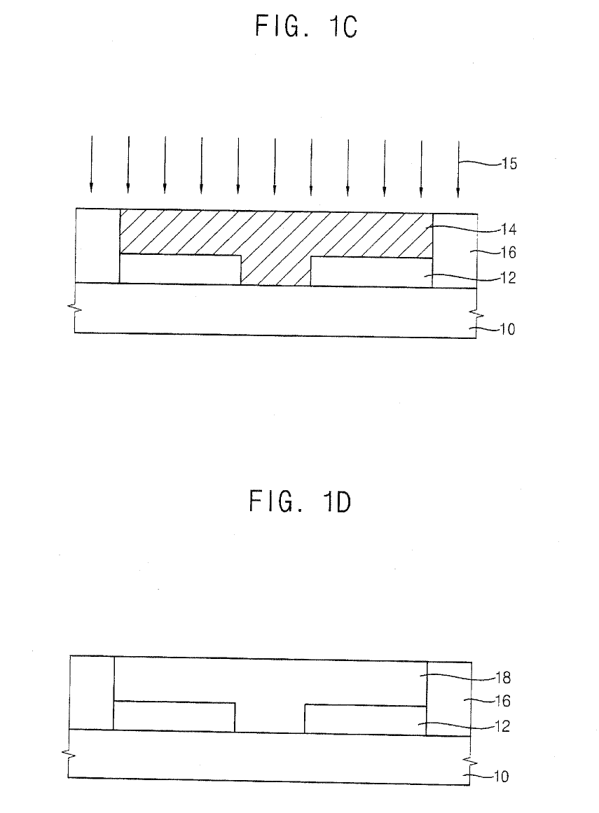

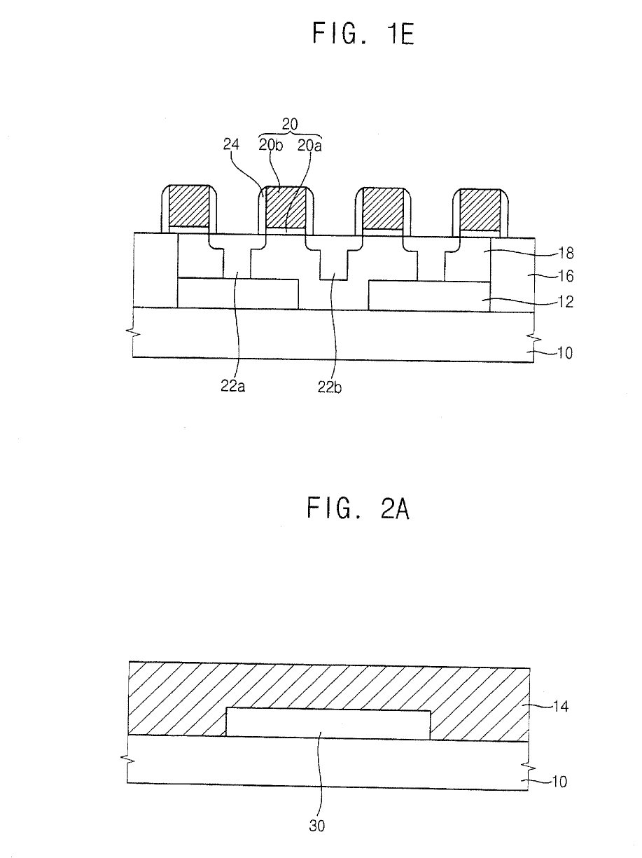

FIGS. 1A to 1E are cross-sectional views illustrating a method of manufacturing a semiconductor device in accordance with an example embodiment of the present invention.

Referring to FIG. 1A, a semiconductor substrate 10 is provided. The substrate 10 may be a bulk semiconductor substrate. The substrate 10 may include a single crystalline material. For example, the single crystalline material may be single crystalline silicon, single crystalline germanium, single crystalline silicon-germanium, etc. In an example embodiment of the present invention, the substrate 10 may include single crystalline silicon.

An insulating layer is formed on the substrate 10. For example, the insulating layer may include an oxide. In addition, the insulating layer may be formed by a thermal oxidation process.

The insulating layer may then be patterned. Specifically, the insulating layer may be patterned by an etching process employing a photoresist pattern as an etch mask. Accordingly, the insulating layer is transformed into an insulating layer pattern 12 defining an opening 13 partially exposing the substrate 10. In an example embodiment, the opening 13 is formed by partially etching a central portion of the insulating layer. For example, the insulating layer pattern 12 may enclose sidewalls of the opening 13. In addition, the insulating layer pattern 12 may include an oxide substantially similar to the insulating layer.

Referring to FIG. 1B, an amorphous thin layer 14 is formed on the substrate 10 on which the insulating layer pattern 12 is formed after the insulating layer pattern 12 is formed. The amorphous thin layer 14 may be sufficiently formed to cover the insulating layer pattern 12. For example, the amorphous thin layer 14 may be formed by a chemical vapor deposition (CVD) process. In addition, when a stepped portion is formed at an upper surface of the amorphous thin layer 14, a planarization process such as a chemical mechanical polishing (CMP) process and an etch-back process may be performed to remove the stepped portion after the amorphous thin layer 14 is formed.

As examples, the amorphous thin layer 14 may include amorphous silicon, amorphous germanium, amorphous silicon-germanium, etc. In the present embodiment, the amorphous thin layer 14 includes the amorphous silicon because the substrate 10 includes single crystalline silicon.

Referring to FIGS. 1C and 1D, portions of the amorphous thin layer 14 located laterally adjacent to both side portions of the insulating layer pattern 12 may be removed after the amorphous thin layer 14 is formed. For example, the portions of the amorphous thin layer 14 may be removed until a portion of the substrate 10 is exposed. An isolating material such as an oxide may be deposited on the exposed portion of the substrate 10 so that an isolation layer 16 may be formed adjacent to both side portions of the insulating layer pattern 12. Preferably, a height of the isolation layer 16 may be substantially the same as a height of the amorphous thin layer 14. Thus, in the case that the height of the isolation layer 16 is substantially greater than that of the amorphous thin layer 14, the isolation layer 16 and the amorphous thin layer 14 may be planarized by a CMP process and/or an etch-back process.

In an example embodiment, the opening 13 of the insulating layer pattern 12 may be located at a central portion of the insulating layer pattern 12. In addition, the isolation layer 16 may be formed adjacent to the both side portions of the insulating layer pattern 12.

As mentioned above, the isolation layer 16, which is structurally similar to a trench isolation layer, may be formed after the insulating layer pattern 12 is formed on the substrate 10. Thus, the isolation layer 16 may effectively be formed regardless of a gap-filling characteristic of the insulating material.

In an example embodiment, the portions of the amorphous thin layer 14 adjacent to the both side portions of the insulating layer pattern 12 are removed to form the isolation layer 16. Alternatively, the insulating layer pattern 12 as well as the amorphous thin layer 14 may be removed to form the isolation layer 16.

A laser beam 15 may be irradiated onto the amorphous thin layer 14 after the isolation layer 16 is formed. The laser beam 15 may have sufficient energy to melt the amorphous thin layer 14.

When the laser beam 15 is irradiated onto the amorphous thin layer 14, a phase of the amorphous thin layer 14 may be changed. Particularly, the laser beam 15 irradiated onto the amorphous thin layer 14 may melt the amorphous thin layer 14 so that the phase of the amorphous thin layer 14 may be changed from a solid phase into a liquid phase. Additionally, a phase change of the amorphous thin layer 14 may occur from an upper surface of the amorphous thin layer 14 to an interface between the amorphous thin layer 14 and a portion of the substrate 10 corresponding to the opening 13. For example, when the phase change of the amorphous thin layer 14 occurs, the phase of the amorphous thin layer 14 may be changed into a single crystalline state. Here, the substrate 10 including a single crystalline material may be used as a seed.

As mentioned above, the irradiating laser beam 15 may have enough energy to melt the entire amorphous thin layer 14 because the phase change of the amorphous thin layer 14 occurs from the upper surface of the amorphous thin layer 14 to the interface between the amorphous thin layer 14 and the portion of the substrate 10 corresponding to the opening 13. The amorphous thin layer 14 may include silicon having a melting point of about 1,410C. Thus, the laser beam 15 may be adjusted to have energy capable of achieving a temperature above about 1,410° C. Alternatively, the amorphous thin layer 12 may include germanium having a melting point of about 958.5° C. Here, the laser beam 15 may be adjusted to have energy capable of achieving a temperature above about 958.5° C.

The phase change of the amorphous thin layer 14 may occur in vertical and horizontal directions. Here, it takes about a few nano seconds for changing the phase of the amorphous thin layer 14. Thus, the amorphous thin layer 14 may not flow from the substrate 10 even though the phase of the amorphous thin layer 14 is changed into a liquid phase.

When the phase of the amorphous thin layer 14 is changed by the laser beam 15, a resultant layer including the amorphous thin layer 14 may be thermally treated to decrease a thermal gradient in the amorphous thin layer 14. When the thermal gradient in the amorphous thin layer 14 decreases, grains having relatively large sizes may be effectively formed in the amorphous thin layer 14. When the amorphous thin layer 14 is thermally treated at a temperature below about 200° C., a size of the grains may not be sufficiently large. When the amorphous thin layer 14 is thermally treated at a temperature above about 600° C., it is difficult to prepare an apparatus for thermally treating the amorphous thin layer 14. Therefore, the resultant layer including the amorphous thin layer 14 may be thermally treated at a temperature of about 200° C. to about 600° C. For example, the resultant layer including the amorphous thin layer 14 may be thermally treated at a temperature of about 350° C. to about 450° C.

As mentioned above, the phase of the amorphous thin layer 14 may be changed by the laser beam 15 irradiated onto the amorphous thin layer 14. When the phase of the amorphous thin layer 14 is changed, the amorphous thin layer 14 may be changed into a single crystalline thin layer 18. This is because the substrate 10 including the single crystalline material is used as a seed when the phase of the amorphous thin layer 14 is changed. The single crystalline thin layer 18 may actually be a polycrystalline layer having a large grain size such that it appears single crystalline on the scale of a unit device subsequently formed on the single crystalline thin layer 18.

As an example, the amorphous thin layer 14 may include silicon so that the single crystalline thin layer 18 may also include silicon. Therefore, the single crystalline thin layer 18 changed from the amorphous thin layer 14 may include single crystalline silicon.

As mentioned above, the insulating layer pattern 12 and the single crystalline thin layer 18 are sequentially formed on the substrate 10 by performing relatively simple processes. The substrate 10 on which the insulating layer pattern 12 and the single crystalline thin layer 18 are sequentially formed may be obtained by performing processes shown in FIGS. 1A to 1D.

Referring to FIG. 1E, a unit device such as a metal oxide semiconductor field effect transistor (MOSFET) may be formed on the single crystalline thin layer 18 after the single crystalline thin layer 18 is formed. Particularly, a gate pattern 20 including a gate insulating layer 20a and a gate conductive layer 20b is formed on the single crystalline thin layer 18. Source/drain regions 22a and 22b are formed at a surface portion of the single crystalline thin layer 18 adjacent to both sidewalls of the gate pattern 20. A gate spacer 24 may be formed on both sidewalls of the gate pattern 20. When gate spacer 24 is formed on both sidewalls of the gate pattern 20, the source/drain regions 22a and 22b may have lightly doped drain (LDD) structures.

According to an example embodiment of the present invention, the substrate 10 on which the insulating layer pattern 12 and the single crystalline thin layer 18 are sequentially formed may be effectively obtained. Thus, the unit device such as the MOSFET may be effectively formed on the single crystalline thin layer 18 that is formed on the substrate 10. Therefore, when the above processes are employed to manufacture a semiconductor device, the semiconductor device may have the advantages generally obtained by applying techniques such as a silicon-on-insulator (SOI) process.

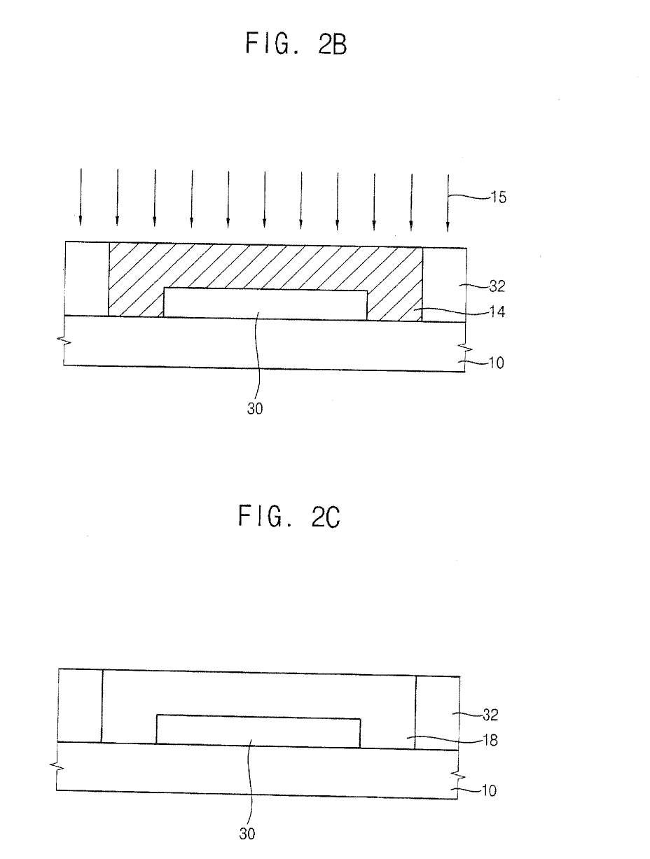

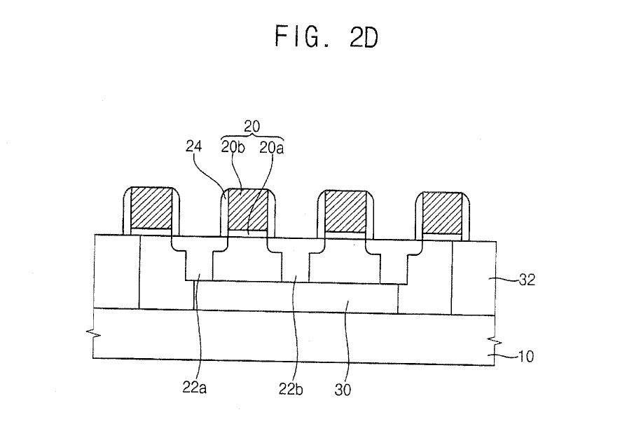

FIGS. 2A to 2D are cross-sectional views illustrating a method of manufacturing a semiconductor device in accordance with another example embodiment of the present invention. The semiconductor device may be similar to the semiconductor device illustrated in FIGS. 1A to 1E. Thus, the same reference numerals will be used to refer to the same or like parts as those described in FIGS. 1A to 1E, and any further explanations will be omitted.

Referring to FIG. 2A, a substrate 10 is provided. An insulating layer pattern 30 defining openings may be formed by patterning the insulating layer after the insulating layer is formed on the substrate 10. The insulating layer pattern 30 may define the openings adjacent to both side portions of the insulating layer pattern 30. In contrast to the opening 13 shown in FIGS. 1A to 1E, the openings of the present embodiment may not be provided through a central portion of the insulating layer pattern 30. Specifically, a sidewall of the openings may correspond to the side portions of the insulating layer pattern 30 in the present embodiment. An amorphous thin layer 14 may then be formed on the insulating layer pattern 30.

Referring to FIGS. 2B and 2C, an isolation layer 32 may be formed on the substrate 10 after the amorphous thin layer 14 is formed. For example, the isolation layer 32 may be spaced apart from both side portions of the insulating layer pattern 30. Accordingly, portions of the substrate 10 between the insulating layer pattern 30 and the isolation layer 32 may be exposed. The exposed portions of the substrate 10 may correspond to the openings of the insulating layer pattern 30. When a phase of the amorphous thin layer 14 is subsequently changed by a laser beam 15 irradiated onto the amorphous thin layer 14, the substrate 10 may be used as a seed because the substrate 10 is exposed.

The laser beam 15 is then irradiated onto the amorphous thin layer 14. For example, the irradiation of the laser beam 15 may be substantially the same as that illustrated in FIG. 1C. Thus, any further explanation will be omitted. The amorphous thin layer 14 may be changed into a single crystalline thin layer 18 by the laser beam 15.

Referring to FIG. 2D, a gate pattern 20 including a gate insulating layer 20a and a gate conductive layer 20b is formed on the single crystalline thin layer 18 after the single crystalline thin layer 18 is formed. Source/drain regions 22a and 22b are formed at surface portions of the single crystalline thin layer 18 adjacent to both sidewalls of the gate pattern 20.

According to an example embodiment of the present invention, the substrate 10 on which the insulating layer pattern 12 and the single crystalline thin layer 18 are sequentially formed may be effectively obtained. Thus, a unit device such as a MOSFET may be effectively formed on the single crystalline thin layer 18 formed on the substrate 10.

According to embodiments of the present invention, when the above processes are employed to manufacture a semiconductor device, the semiconductor device may have the advantages generally obtained by applying techniques such as a silicon-on-insulator (SOI) process. Therefore, the semiconductor device manufactured by the above manufacturing methods of the present invention may have a relatively high integration degree and a relatively high operation speed.

In accordance with an embodiment of the present invention, there is provided a method of manufacturing a semiconductor device. In the method, an insulating layer pattern defining at least one opening partially exposing a semiconductor substrate is formed on the semiconductor substrate including a single crystalline material. An amorphous layer is then formed on the insulating layer pattern to fill up the opening. The amorphous layer is then transformed into a single crystalline layer by providing the amorphous layer with a laser beam having sufficient energy to melt the amorphous layer. The semiconductor substrate partially exposed through the opening is used as a seed when the melted amorphous layer is transformed into the single crystalline layer.

Thus, the semiconductor substrate on which the insulating layer pattern and the single crystalline layer are formed may be effectively obtained.

In accordance with another embodiment of the present invention, a method of manufacturing a semiconductor device is provided. In the method, an insulating layer pattern defining at least one opening partially exposing a semiconductor substrate is formed on the semiconductor substrate including a single crystalline material. An amorphous layer is then formed on the insulating layer pattern to fill up the opening. The amorphous layer is then transformed into a single crystalline layer by providing the amorphous layer with a laser beam having sufficient energy to melt the amorphous layer. The semiconductor substrate partially exposed through the opening is used as a seed when the melted amorphous layer is transformed into the single crystalline layer. A gate pattern is then formed on the single crystalline layer. Source/drain regions are formed at surface portions of the single crystalline layer adjacent to both sidewalls of the gate pattern.

Thus, a unit device such as a metal oxide semiconductor field effect transistor (MOSFET) may be effectively formed using the single crystalline layer formed on the semiconductor substrate.

Here, examples of a material included in the semiconductor substrate may be single crystalline silicon, single crystalline germanium, single crystalline silicon-germanium, etc.

An isolation layer may be further formed on the semiconductor substrate to manufacture the semiconductor device. When the opening is provided through a central portion of the insulating layer pattern, the isolation layer is formed such that the isolation layer makes contact with both side portions of the insulating layer pattern. When the at least one opening comprises two openings and each of the openings is provided adjacent to both side portions of the insulating layer pattern, the isolation layer is formed such that the isolation layer is spaced apart from the both side portions of the insulating layer pattern.

According to an example embodiment of the present invention, the semiconductor substrate on which the insulating layer pattern and the single crystalline layer are sequentially formed may be effectively obtained. Thus, the unit device such as the MOSFET may be effectively formed on the single crystalline layer formed on the semiconductor substrate.

Therefore, when the above processes are employed to manufacture the semiconductor device, the semiconductor device may efficiently have advantages generally obtained by applying techniques such as a silicon-on-insulator (SOI) process.

According to some embodiments of the present invention, a method of manufacturing a semiconductor device comprises: forming an insulating layer pattern on a semiconductor substrate, the insulating layer pattern defining at least one opening exposing a portion of the semiconductor substrate; forming a semiconductor layer on the insulating layer pattern, the semiconductor layer disposed in the opening and in contact with the semiconductor substrate; and irradiating the semiconductor layer with a laser beam, thereby forming a crystalline layer. Irradiating the semiconductor layer may include melting the semiconductor layer.

According to some embodiments, the method may further include thermally treating the semiconductor layer at a temperature of about 200° C. to about 600° C. The method may also include forming an isolation layer on the semiconductor substrate.

According to some embodiments, the opening is disposed through a central portion of the insulating layer pattern. In this case, the isolation layer may be disposed adjacent to side portions of the insulating layer pattern.

According to other embodiments, the opening comprises two openings disposed at side portions of the insulating layer pattern. In this case, the isolation layer may be spaced apart from the side portions of the insulating layer pattern.

According to some embodiments, forming the isolation layer may comprise etching the semiconductor layer and the insulating layer pattern.

The foregoing is illustrative of the present invention and is not to be construed as limiting thereof. Although a few embodiments of this invention have been described, those skilled in the art will readily appreciate that many modifications are possible in the embodiments without materially departing from the novel teachings and advantages of this invention. Accordingly, all such modifications are intended to be included within the scope of this invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. T he invention is defined by the following claims, with equivalents of the claims to be included therein.

What is claimed is:

1. A method of manufacturing a semiconductor device, the method comprising:
forming an insulating layer pattern on a semiconductor substrate including a single crystalline material, the insulating layer pattern defining at least one opening partially exposing the semiconductor substrate;
forming an amorphous layer on the insulating layer pattern to fill up the opening; and
transforming the amorphous layer into a single crystalline layer by providing the amorphous layer with a laser beam having sufficient energy to melt the amorphous layer, wherein the semiconductor substrate partially exposed through the opening is used as a seed when the melted amorphous layer is transformed into the single crystalline layer.

2. The method of claim 1, wherein the semiconductor substrate comprises single crystalline silicon, single crystalline germanium or single crystalline silicon-germanium.

3. The method of claim 1, wherein the insulating layer pattern comprises oxide.

4. The method of claim 1, further comprising thermally treating the amorphous layer at a temperature of about 200° C. to about 600° C. using the laser beam.

5. A method of manufacturing a semiconductor device, the method comprising:
forming an insulating layer pattern on a semiconductor substrate including a single crystalline material, the insulating layer pattern defining at least one opening partially exposing the semiconductor substrate;
forming an amorphous layer on the insulating layer pattern to fill up the opening;
transforming the amorphous layer into a single crystalline layer by providing the amorphous layer with a laser beam having sufficient energy to melt the amorphous layer, the semiconductor substrate partially exposed through the opening being used as a seed when the melted amorphous layer is transformed into the single crystalline layer;
forming a gate pattern on the single crystalline layer; and
forming source/drain regions at surface portions of the single crystalline layer adjacent to both sidewalls of the gate pattern.

6. The method of claim 5, wherein the semiconductor substrate comprises single crystalline silicon, single crystalline germanium or single crystalline silicon-germanium.

7. The method of claim 5, wherein the insulating layer pattern comprises oxide.

8. The method of claim 5, further comprising thermally treating the amorphous layer at a temperature of about 200° C. to about 600° C. using the laser beam.

9. The method of claim 5, further comprising forming an isolation layer on the semiconductor substrate.

10. The method of claim 9, wherein the opening is provided through a central portion of the insulating layer pattern and the isolation layer makes contact with both side portions of the insulating layer pattern.

11. The method of claim 9, wherein the at least one opening comprises two openings, each of the openings is disposed adjacent to a side portion of the insulating layer pattern, and the isolation layer is spaced apart from the side portions of the insulating layer pattern adjacent to the openings.

12. A method of manufacturing a semiconductor device, the method comprising:
forming an insulating layer pattern on a semiconductor substrate, the insulating layer pattern defining at least one opening exposing a portion of the semiconductor substrate;
forming a semiconductor layer on the insulating layer pattern, the semiconductor layer disposed in the opening and in contact with the semiconductor substrate; and
irradiating the semiconductor layer with a laser beam, thereby forming a crystalline layer.

13. The method of claim 12, wherein irradiating the semiconductor layer comprises melting the semiconductor layer.

14. The method of claim 12, further comprising thermally treating the semiconductor layer at a temperature of about 200° C. to about 600° C.

15. The method of claim 12, further comprising forming an isolation layer on the semiconductor substrate.

16. The method of claim 15, wherein the opening is disposed through a central portion of the insulating layer pattern.

17. The method of claim 16, wherein the isolation layer is disposed adjacent to side portions of the insulating layer pattern.

18. The method of claim 15, wherein the opening comprises two openings disposed at side portions of the insulating layer pattern.

19. The method of claim 18, wherein the isolation layer is spaced apart from the side portions of the insulating layer pattern.

20. The method of claim 15, wherein forming the isolation layer comprises etching the semiconductor layer and the insulating layer pattern.
